(19) United States
(12) Patent Application Publication
(10) Pub. No.: US 2023/0360935 A1
(43) Pub. Date: Nov. 9, 2023

(54) DIE PLACEMENT FOR VARACTORS IN ANTENNAS AND METHOD FOR SAME

(71) Applicant: Kymeta Corporation, Redmond, WA (US)

(72) Inventors: Steven Howard Linn, III, Hillsboro, OR (US); Cagdas Varel, Seattle, WA (US)

(21) Appl. No.: 18/142,840

(22) Filed: May 3, 2023

Related U.S. Application Data
(60) Provisional application No. 63/339,315, filed on May 6, 2022.

(51) Int. Cl. H01L 21/67; H01L 21/683; H05K 13/04

(52) U.S. Cl. CPC H01L 21/67132; H01L 21/6836; H05K 13/04; H01Q 3/26

(57) ABSTRACT

An apparatus for die placement for varactors or other devices in antennas and methods for using the same are disclosed. In some embodiments, a method for manufacturing an antenna aperture comprises: placing at least one portion of an antenna aperture on a platen that is radially revolvable, the at least one portion of the antenna aperture having a plurality of antenna elements; placing a plurality of dies on the at least one portion of the antenna aperture using a pick and place machine, including radially revolving the platen with the machine to position each antenna element of the plurality of antenna elements of the at least one portion of the antenna aperture with respect to the pick and place machine for placement of each die of the plurality of dies, and placing said each die of the plurality of dies on the at least one portion of the antenna aperture segment.

### RELATED APPLICATION

The present application is a non-provisional application of and claims the benefit of U.S. Provisional Patent Application No. 63/339,315, filed May 6, 2022, and entitled “OPTIMIZED DIE PLACEMENT FOR VARACTOR SEGMENTS/APERTURES”, which is incorporated by reference in its entirety.

### FIELD OF THE DISCLOSURE

Embodiments disclosed herein are related to wireless communication; more particularly, embodiments disclosed herein relate to placing dies on an antenna aperture using pick and place techniques.

### BACKGROUND

Metasurface antennas have recently emerged as a new technology for generating steered, directive beams from a lightweight, low-cost, and planar physical platform. Such metasurface antennas have been recently used in a number of applications, such as, for example, satellite communication.

Metasurface antennas may comprise metamaterial antenna elements that can selectively couple energy from a feed wave to produce beams that may be controlled for use in communication. These antennas can achieve comparable performance to phased array antennas from an inexpensive and easy-to-manufacture hardware platform. By tuning the constituent metamaterial elements' characteristics, a hologram at the aperture plane can be achieved, in which the waveguide mode acts as the reference wave and the collection of tuned elements form the hologram. The collective radiation from these holographic antennas can thereby be modulated to form arbitrary patterns by use of electronic tuning.

Many of the metasurface antennas include antenna apertures with multiple integrated circuit (IC) dies. Traditionally, die placement is performed one die at a time and it is a slow process. One estimate for placing light-emitting diodes (LEDs) on a display was roughly 4-6 die/second, which would take approximately 2.9 hours per segment if placing 41000 die in the segment. To achieve volume manufacturing while meeting cost goals requires rethinking this process. Some metasurface antennas have a circular or radial shape. However, current die placement techniques do not take advantage of the radial nature of some metasurface RF antenna apertures.

The dies used in metasurface antennas are created as part of wafers and undergo processing to enable them to be placed subsequently on an antenna aperture. Typically, die processing on wafers relies on Cartesian “step and repeat” methods to form dies on semiconductor wafers. Therefore, typical semiconductor dies are produced in Cartesian coordinate grids. Thus, when performing the process of placing these dies onto radial antennas, there is no symmetry between where the dies are obtained for placement and the symmetry of radial antennas.

### SUMMARY

An apparatus for die placement for varactors or other devices in antennas and methods for using the same are disclosed. In some embodiments, a method for manufacturing an antenna aperture comprises: placing at least one portion of an antenna aperture on a platen that is radially revolvable, the at least one portion of the antenna aperture having a plurality of antenna elements; placing a plurality of dies on the at least one portion of the antenna aperture using a pick and place machine, including radially revolving the platen with the machine to position each antenna element of the plurality of antenna elements of the at least one portion of the antenna aperture with respect to the pick and place machine for placement of each die of the plurality of dies, and placing said each die of the plurality of dies on the at least one portion of the antenna aperture segment.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 illustrates an exploded view of some embodiments of a flat-panel antenna.

FIG. 2 illustrates an example of a communication system that includes one or more antennas described herein.

FIG. 3 illustrates the die placement arrangement for placing dies on an aperture.

FIG. 4 illustrates portions of a pair of RF antenna elements.

FIG. 5A illustrates some embodiments in which the die orientation required by the RF antenna elements in the +45 degree orientation is set to enable a pick and place machine to pick and place individual dies by rotating the dies 180 degrees using the nozzle of the rotating placement arm of a pick and place machine.

FIG. 5B illustrates the placement of dies required by the RF antenna elements in the −45 degree orientation.

FIG. 6 illustrates some embodiments of the die placement apparatus where the dies on the tape are held at 0 or 90 degrees with respect to the revolving placement arms of the die placement tool.

FIGS. 7A and 7B illustrate mirroring of the RF element are their associated bond pads.

FIG. 8 illustrates the die orientation rotated by 180 degrees on a column by column basis.

FIG. 9 illustrates a placement method for placing a die where a TFT connection is desired to be oriented toward the aperture center.

FIGS. 10A and 10B illustrate die placements performed such that the iris elements of the bond pads are oriented at 45 degrees in a mirrored configuration between the two different rotations.

FIG. 11 illustrates two RF antenna elements being added to each quadrant for each ring pitch increment.

FIG. 12 is an example of a segment placement table.

FIG. 13 illustrates placing two die at a time in some portions of an aperture or aperture segment.

### DETAILED DESCRIPTION

In the following description, numerous details are set forth to provide a more thorough explanation of embodiments of the present disclosure. It will be apparent, however, to one skilled in the art, that the teachings disclosed herein may be practiced without these specific details. In other instances, well-known structures and devices are shown in block diagram form, rather than in detail, in order to avoid obscuring the present disclosure.

Embodiments described herein include improved techniques for placing dies on a metasurface radio-frequency (RF) antenna aperture having multiple RF radiating antenna elements. In some embodiments, the RF radiating antenna elements comprise a tuning element that is part of the die. In some embodiments, the RF radiating antenna elements comprise varactor-based antenna elements in which the die is varactor diode. In some other embodiments, the RF radiating antenna elements comprise liquid crystal (LC)-based antenna elements with LC as the tuning element. In yet some other embodiments, the RF radiating antenna elements comprise micro-electromechanical system (MEMS)-based antenna elements where the tuning element for each RF radiating antenna element comprise an RF MEMS. These techniques include changes in wafer design, antenna segment layouts, and the placement equipment.

The following disclosure discusses examples of antenna embodiments followed by a description of techniques for placing dies on a metasurface or other type of antenna aperture.

### Examples of Antenna Embodiments

The techniques described herein may be used with a variety of flat panel satellite antennas. Embodiments of such flat panel antennas are disclosed herein. In some embodiments, the flat panel satellite antennas are part of a satellite terminal. The flat panel antennas include one or more arrays of antenna elements on an antenna aperture.

In some embodiments, the antenna aperture is a metasurface antenna aperture, such as, for example, the antenna apertures described below. In some embodiments, the antenna elements comprise radio-frequency (RF) radiating antenna elements. In some embodiments, the antenna elements include tunable devices to tune the antenna elements. Examples of such tunable devices include diodes and varactors such as, for example, described in U.S. Pat. No. 11,489,266, entitled “Metasurface Antennas Manufactured with Mass Transfer Technologies,” issued Nov. 1, 2022. In some other embodiments, the antenna elements comprise liquid crystal (LC)-based antenna elements, such as, for example, those disclosed in U.S. Pat. No. 9,887,456, entitled “Dynamic Polarization and Coupling Control from a Steerable Cylindrically Fed Holographic Antenna”, issued Feb. 6, 2018, or other RF radiating antenna elements. It should be appreciated that other tunable devices such as, for example, but not limited to, tunable capacitors, tunable capacitance dies, packaged dies, micro-electromechanical systems (MEMS) devices, or other tunable capacitance devices, could be placed into an antenna aperture or elsewhere in variations on the embodiments described herein.

In some embodiments, the antenna aperture having the one or more arrays of antenna elements is comprised of multiple segments that are coupled together. In some embodiments, when coupled together, the combination of the segments form groups of antenna elements (e.g., closed concentric rings of antenna elements concentric with respect to the antenna feed, etc.). For more information on antenna segments, see U.S. Pat. No. 9,887,455, entitled “Aperture Segmentation of a Cylindrical Feed Antenna”, issued Feb. 6, 2018.

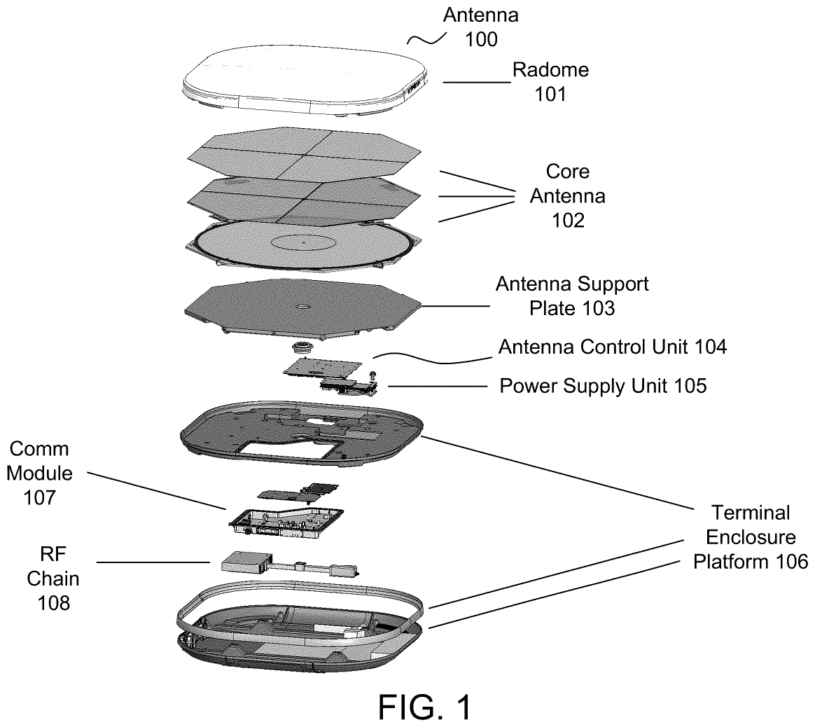

FIG. 1 illustrates an exploded view of some embodiments of a flat-panel antenna. Referring to FIG. 1, antenna 100 comprises a radome 101, a core antenna 102, antenna support plate 103, antenna control unit (ACU) 104, a power supply unit 105, terminal enclosure platform 106, comm (communication) module 107, and RF chain 108.

Radome 101 is the top portion of an enclosure that encloses core antenna 102. In some embodiments, radome 101 is weatherproof and is constructed of material transparent to radio waves to enable beams generated by core antenna 102 to extend to the exterior of radome 101.

In some embodiments, core antenna 102 comprises an aperture having RF radiating antenna elements. These antenna elements act as radiators (or slot radiators). In some embodiments, the antenna elements comprise scattering metamaterial antenna elements. In some embodiments, the antenna elements comprise both Receive (Rx) and Transmit (Tx) irises, or slots, that are interleaved and distributed on the whole surface of the antenna aperture of core antenna 102. Such Rx and Tx irises may be in groups of two or more sets where each set is for a separately and simultaneously controlled band. Examples of such antenna elements with irises are described in U.S. Pat. No. 10,892,553, entitled “Broad Tunable Bandwidth Radial Line Slot Antenna”, issued Jan. 12, 2021.

In some embodiments, the antenna elements comprise irises (iris openings) and the aperture antenna is used to generate a main beam shaped by using excitation from a cylindrical feed wave for radiating the iris openings through tunable elements (e.g., diodes, varactors, patch, etc.). In some embodiments, the antenna elements can be excited to radiate a horizontally or vertically polarized electric field at desired scan angles.

In some embodiments, a tunable element (e.g., diode, varactor, patch etc.) is located over each iris slot. The amount of radiated power from each antenna element is controlled by applying a voltage to the tunable element using a controller in ACU 104. Traces in core antenna 102 to each tunable element are used to provide the voltage to the tunable element. The voltage tunes or detunes the capacitance and thus the resonance frequency of individual elements to effectuate beam forming. The voltage required is dependent on the tunable element in use. Using this property, in some embodiments, the tunable element (e.g., diode, varactor, LC, etc.) integrates an on/off switch for the transmission of energy from a feed wave to the antenna element. When switched on, an antenna element emits an electromagnetic wave like an electrically small dipole antenna. Note that the teachings herein are not limited to having unit cell that operates in a binary fashion with respect to energy transmission. For example, in some embodiments in which varactors are the tunable element, there are 32 tuning levels. As another example, in some embodiments in which LC is the tunable element, there are 16 tuning levels.

A voltage between the tunable element and the slot can be modulated to tune the antenna element (e.g., the tunable resonator/slot). Adjusting the voltage varies the capacitance of a slot (e.g., the tunable resonator/slot). Accordingly, the reactance of a slot (e.g., the tunable resonator/slot) can be varied by changing the capacitance. Resonant frequency of the slot also changes according to the equation

$$f = \frac{1}{2 π \sqrt{LC}}$$

where f is the resonant frequency of the slot and L and C are the inductance and capacitance of the slot, respectively. The resonant frequency of the slot affects the energy coupled from a feed wave propagating through the waveguide to the antenna elements.

In particular, the generation of a focused beam by the metamaterial array of antenna elements can be explained by the phenomenon of constructive and destructive interference, which is well known in the art. Individual electromagnetic waves sum up (constructive interference) if they have the same phase when they meet in free space to create a beam, and waves cancel each other (destructive interference) if they are in opposite phase when they meet in free space. If the slots in core antenna 102 are positioned so that each successive slot is positioned at a different distance from the excitation point of the feed wave, the scattered wave from that antenna element will have a different phase than the scattered wave of the previous slot. In some embodiments, if the slots are spaced one quarter of a wavelength apart, each slot will scatter a wave with a one fourth phase delay from the previous slot. In some embodiments, by controlling which antenna elements are turned on or off (i.e., by changing the pattern of which antenna elements are turned on and which antenna elements are turned off) or which of the multiple tuning levels is used, a different pattern of constructive and destructive interference can be produced, and the antenna can change the direction of its beam(s).

In some embodiments, core antenna 102 includes a coaxial feed that is used to provide a cylindrical wave feed via an input feed, such as, for example, described in U.S. Pat. No. 9,887,456, entitled “Dynamic Polarization and Coupling Control from a Steerable Cylindrically Fed Holographic Antenna”, issued Feb. 6, 2018 or in U.S. Pat. No. 11,489,266, entitled “Metasurface Antennas Manufactured with Mass Transfer Technologies,” issued Nov. 1, 2022. In some embodiments, the cylindrical wave feed feeds core antenna 102 from a central point with an excitation that spreads outward in a cylindrical manner from the feed point. In other words, the cylindrically fed wave is an outward travelling concentric feed wave. Even so, the shape of the cylindrical feed antenna around the cylindrical feed can be circular, square or any shape. In some other embodiments, a cylindrically fed antenna aperture creates an inward travelling feed wave. In such a case, the feed wave most naturally comes from a circular structure.

In some embodiments, the core antenna comprises multiple layers. These layers include the one or more substrate layers forming the RF radiating antenna elements. In some embodiments, these layers may also include impedance matching layers (e.g., a wide-angle impedance matching (WAIM) layer, etc.), one or more spacer layers and/or dielectric layers. Such layers are well-known in the art.

Antenna support plate 103 is coupled to core antenna 102 to provide support for core antenna 102. In some embodiments, antenna support plate 103 includes one or more waveguides and one or more antenna feeds to provide one or more feed waves to core antenna 102 for use by antenna elements of core antenna 102 to generate one or more beams.

ACU 104 is coupled to antenna support plate 103 and provides controls for antenna 100. In some embodiments, these controls include controls for drive electronics for antenna 100 and a matrix drive circuitry to control a switching array interspersed throughout the array of RF radiating antenna elements. In some embodiments, the matrix drive circuitry uses unique addresses to apply voltages onto the tunable elements of the antenna elements to drive each antenna element separately from the other antenna elements. In some embodiments, the drive electronics for ACU 104 comprise commercial off-the shelf LCD controls used in commercial television appliances that adjust the voltage for each antenna element.

More specifically, in some embodiments, ACU 104 supplies an array of voltage signals to the tunable devices of the antenna elements to create a modulation, or control, pattern. The control pattern causes the elements to be tuned to different states. In some embodiments, ACU 104 uses the control pattern to control which antenna elements are turned on or off (or which of the tuning levels is used) and at which phase and amplitude level at the frequency of operation. The elements are selectively detuned for frequency operation by voltage application. In some embodiments, multistate control is used in which various elements are turned on and off to varying levels, further approximating a sinusoidal control pattern, as opposed to a square wave (i.e., a sinusoid gray shade modulation pattern).

In some embodiments, ACU 104 also contains one or more processors executing the software to perform some of the control operations. ACU 104 may control one or more sensors (e.g., a GPS receiver, a three-axis compass, a 3-axis accelerometer, 3-axis gyro, 3-axis magnetometer, etc.) to provide location and orientation information to the processor(s). The location and orientation information may be provided to the processor(s) by other systems in the earth station and/or may not be part of the antenna system.

Antenna 100 also includes a comm (communication) module 107 and an RF chain 108. Comm module 107 includes one or more modems enabling antenna 100 to communicate with various satellites and/or cellular systems, in addition to a router that selects the appropriate network route based on metrics (e.g., quality of service (QoS) metrics, e.g., signal strength, latency, etc.). RF chain 108 converts analog RF signals to digital form. In some embodiments, RF chain 108 comprises electronic components that may include amplifiers, filters, mixers, attenuators, and detectors.

Antenna 100 also includes power supply unit 105 to provide power to various subsystems or parts of antenna 100.

Antenna 100 also includes terminal enclosure platform 106 that forms the enclosure for the bottom of antenna 100. In some embodiments, terminal enclosure platform 106 comprises multiple parts that are coupled to other parts of antenna 100, including radome 101, to enclose core antenna 102.

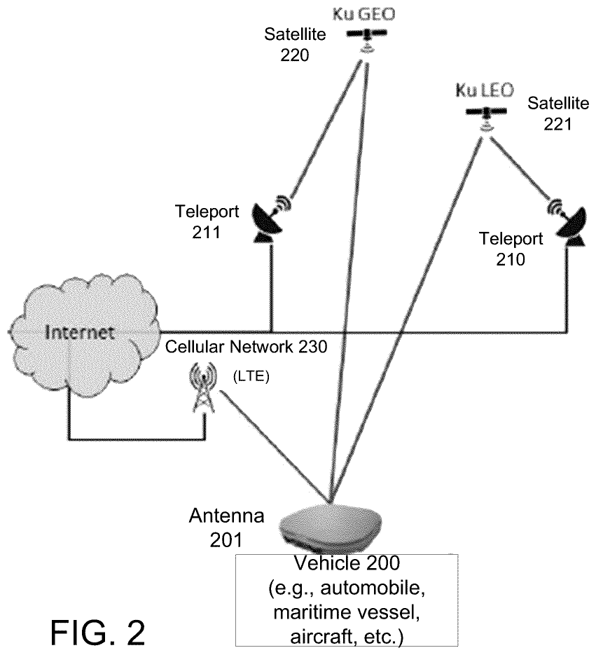

FIG. 2 illustrates an example of a communication system that includes one or more antennas described herein. Referring to FIG. 2, vehicle 200 includes an antenna 201. In some embodiments, antenna 201 comprises antenna 100 of FIG. 1.

In some embodiments, vehicle 200 may comprise any one of several vehicles, such as, for example, but not limited to, an automobile (e.g., car, truck, bus, etc.), a maritime vehicle (e.g., boat, ship, etc.), airplanes (e.g., passenger jets, military jets, small craft planes, etc.), etc. Antenna 201 may be used to communicate while vehicle 200 is either on-the-pause, or moving. Antenna 201 may be used to communicate to fixed locations as well, e.g., remote industrial sites (mining, oil, and gas) and/or remote renewable energy sites (solar farms, windfarms, etc.).

In some embodiments, antenna 201 is able to communicate with one or more communication infrastructures (e.g., satellite, cellular, networks (e.g., the Internet), etc.). For example, in some embodiments, antenna 201 is able to communicate with satellites 220 (e.g., a GEO satellite) and 221 (e.g., a LEO satellite), cellular network 230 (e.g., an LTE, etc.), as well as network infrastructures (e.g., edge routers, Internet, etc.). For example, in some embodiments, antenna 201 comprises one or more satellite modems (e.g., a GEO modem, a LEO modem, etc.) to enable communication with various satellites such as satellite 220 (e.g., a GEO satellite) and satellite 221 (e.g., a LEO satellite) and one or more cellular modems to communicate with cellular network 230. For another example of an antenna communicating with one or more communication infrastructures, see U.S. patent Ser. No. 16/750,439, entitled “Multiple Aspects of Communication in a Diverse Communication Network”, and filed Jan. 23, 2020.

In some embodiments, to facilitate communication with various satellites, antenna 201 performs dynamic beam steering. In such a case, antenna 201 is able to dynamically change the direction of a beam that it generates to facilitate communication with different satellites. In some embodiments, antenna 201 includes multi-beam beam steering that allows antenna 201 to generate two or more beams at the same time, thereby enabling antenna 201 to communication with more than one satellite at the same time. Such functionality is often used when switching between satellites (e.g., performing a handover). For example, in some embodiments, antenna 201 generates and uses a first beam for communicating with satellite 220 and generates a second beam simultaneously to establish communication with satellite 221. After establishing communication with satellite 221, antenna 201 stops generating the first beam to end communication with satellite 220 while switching over to communicate with satellite 221 using the second beam. For more information on multi-beam communication, see U.S. Pat. No. 11,063,661, entitled “Beam Splitting Hand Off Systems Architecture”, issued Jul. 13, 2021.

In some embodiments, antenna 201 uses path diversity to enable a communication session that is occurring with one communication path (e.g., satellite, cellular, etc.) to continue during and after a handover with another communication path (e.g., a different satellite, a different cellular system, etc.). For example, if antenna 201 is in communication with satellite 220 and switches to satellite 221 by dynamically changing its beam direction, its session with satellite 220 is combined with the session occurring with satellite 221.

Thus, the antennas described herein may be part of a satellite terminal that enables ubiquitous communications and multiple different communication connections.

In some embodiments, antenna 201 comprises a metasurface RF antenna having multiple RF radiating antenna elements that are tuned to desired frequencies using RF antenna element drive circuitry. The drive circuitry can include a drive transistor (e.g., a thin film transistor (TFT) (e.g., CMOS, NMOS, etc.), low or high temperature polysilicon transistor, memristor, etc.), a Microelectromechanical systems (MEMS) circuit, or other circuit for driving a voltage to an RF radiating antenna element. In some embodiments, the drive circuitry comprises an active-matrix drive. In some embodiments, the frequency of each antenna element is controlled by an applied voltage. In some embodiments, this applied voltage is also stored in each antenna element (pixel circuit) until the next voltage writing cycle.

### Die Placement Techniques for Antenna Apertures

Embodiments described herein include improved faster methods for placing dies on an antenna aperture. In some embodiments, the antenna aperture comprises a metasurface RF antenna aperture having multiple RF radiating antenna elements (e.g., varactor-based antenna elements, liquid crystal (LC)-based antenna elements, micro-electromechanical system (MEMS)-based antenna elements where the tuning element in the RF metamaterial antenna can be LC, a varactor diode, RF MEMS, respectively). In some embodiments, each RF antenna element includes one or more dies. Some of these dies can be tuning elements to drive a tuning voltage onto an antenna element, such as, for example, but not limited to, diodes, varactors, etc.

In some embodiments, the dies are placed on an antenna aperture using a die placement apparatus that includes a die placement tool. The die placement tool can be a pick and place machine. Using a pick and place machine, there are several possible ways to place die more efficiently on an aperture substrate (e.g., a glass substrate) that forms part of the antenna aperture. One way is to reduce the number of times that dies have to be moved throughout the wafer-to-aperture placement process. Examples of such die movements would be operations such as, for example, but not limited to, sorting, flipping, and placement of the dies. Another way to place die faster on an aperture substrate is to reduce or potentially minimize the time it takes for a die to move from tape carrier or magazine to the destination aperture substrate as short as possible. This time is impacted by the back and forth movements between the tape to the antenna aperture (e.g., a rotating arm moving from the tape to the antenna aperture and then back again) and the average velocity (including acceleration and deceleration) of the die placement tool and the total path length of each die movement. More particularly, some techniques disclosed herein may result in shorter distances the die placement tools have to move to place the die (even while accelerating and decelerating with longer distances). For example, currently an antenna segment is on a x-y table (typical of placing a die on a x-y grid), so the table needs to complete a complicated movement in two axes to accomplish what a few degrees rotation of a rotation table would accomplish ring by ring. More significantly, in order to place die beginning with an (90,0) (or (45,−45) degree orientations) with many varying orientations of elements that can have routing coming in from inner or outer directions, the the antenna aperture segments are picked up and rotated multiple times on an x-y table. This can be avoided by having by adding a rotation table to the x-y table. Such a change can reduce the number of RF element cell designs for a frequency for everyone is unique to a (+45,−45) variety for the frequency.

Also, embodiments disclosed herein include using this feature to reach further back into the process to the wafer and tape. By rotating some die orientations on the same wafer (e.g., same crystal axis, but rotated 180 degrees), dies of two orientations on a tape can eliminate an awkward alternative (e.g., reorientation of the segment, reorientation of a tape, or a long machine movement). If varactor die yields are high enough, by including multiple varactor die types on the same tape, one could make one tape that could be used to place all the dies for an aperture or aperture segment from a single tape, thereby reducing the number of set ups required, the number of tapes of individual die that need to be made, etc. Typically the RF element pattern is one that repeats over and over in an aperture. Taking this to the most efficient case, if the yield is high enough, and since the aperture performance is very tolerant of missing dies, one could place the dies on the wafer in blocks of this repeating pattern, and use these to make tapes, so that one tape might be used to place entire apertures or aperture segments. If the random bad dies are sorted and mapped, their placement can be skipped by not picking them up during that rotation. This takes advantage of the RF nature device to gain efficiency not possible in pick and place of a display, for example.

An additional way to place die faster on an aperture substrate is to move more than one die for each machine movement.

Techniques associated with one or more of these ways for placing dies on antenna apertures are discussed below.

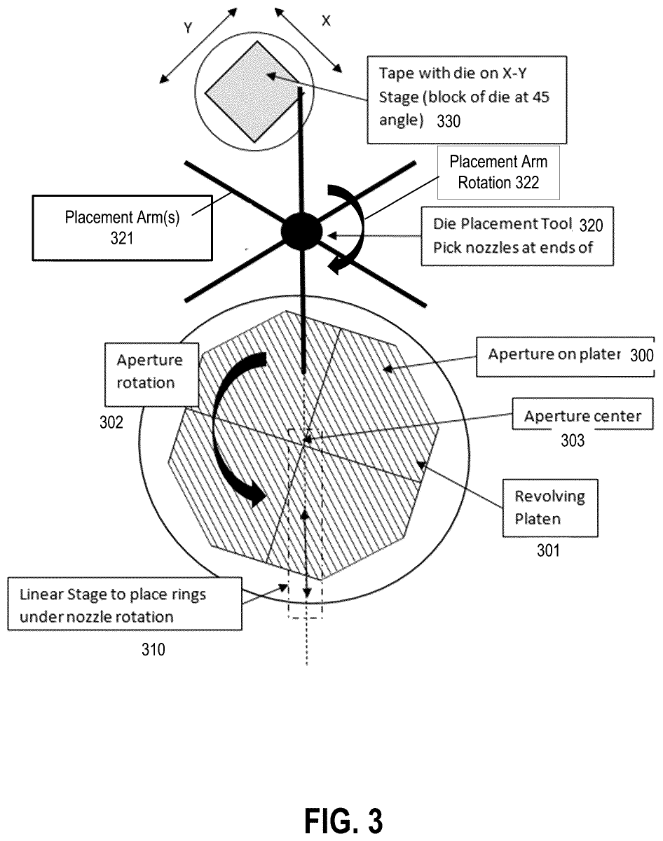

FIG. 3 illustrates the die placement arrangement for placing dies on an aperture. Referring FIG. 3, antenna aperture 300 is placed on a platen 301, which can be controlled to rotate antenna aperture 300 around its center 303. In some embodiments, antenna aperture 300 (or a segment of antenna aperture 300) has a polar symmetry corresponding to an aperture center 303 and rings of RF aperture elements arranged in defined sequences around the aperture center 303. Thus, aperture 300 (or an aperture segment that can be or is used to form aperture 300) is placed on rotatable platen 301 having a corresponding center of rotation where platen 301 is capable of rotating an RF antenna element on antenna aperture 300 at a rotation theta around its center 303. In some embodiments, the rotation of aperture 300 is in a counterclockwise direction (shown as aperture rotation 302). In some other embodiments, the aperture rotation may be clockwise.

The die placement arrangement also includes a die placement tool 320. In some embodiments, die placement tool 320 is placing dies from a tape 330 onto antenna aperture 300. In some embodiments, die placement tool 320 includes a placement arm(s) 321 that has a nozzle at its end that picks up individual dies from tape 330, that rotates to position the dies over the antenna aperture and that place dies onto antenna aperture 300. In some embodiments, die placement tool has multiple placement arms and each has a nozzle to pick up a die from tape 330 (e.g., a spindle with 6 arms/nozzles as shown in FIG. 3, 2 arms, 3 arms, etc.). The rotation of placement arm 321 is shown with the placement arm rotation arrow 322. Tape 330 sits on an X-Y stage that is capable of moving tape 330 in x and y directions to position a die on tape 330 under the nozzle of placement arm 321.

In some embodiments, a wafer containing the dies is made and then placed on tape 330, at which point a cutting process is performed (e.g., dicing saw, laser cutting), so that tape 330 holds all of these parts. Then tape 330 is expanded and placed on a frame such as an X-Y stage, separating the dies. In some embodiments, those dies are flipped, usually by placing them on another tape. The flipping puts the die bond pads (typically upward due to being formed in one of the last steps in the wafer process) down on the tape, so when a die is picked up the die is ready to match pad to pad with the bond pads in the aperture. The tapes can have an adhesive, and the dies can be released from the tape by some method, such as, for example, exposing a part of the tape with a die to heat or ultraviolet (UV) radiation, that makes the adhesive release the die.

In some embodiments, the die placement apparatus also includes a translation linear stage 310 to move platen 301, and the corresponding aperture 300 on top of platen 301, in a linear direction with respect to the rotating placement arm 321 of the die placement tool 320. In some embodiments, the RF antenna elements on antenna aperture 300, to which the dies from tape 330 are placed by the die placement tool 320, are located in rings on antenna aperture 300, and linear, or translation, stage 310 enables the movement of aperture 300 to position an antenna element in a particular ring under the rotating placement arm 321 of the die placement tool 320.

Typically, die placement tool 320 picks a die with the nozzle of a rotating placement arm 321, and the destination has elements on an x,y grid, the bonds location are a repeating orientation for at every die position, and the stage makes small increments in x or y going along a row or going from row to row. The rotating arm of the die placement tool 320 picks up a die oriented at 90 degrees to the radius for the center of the rotating arm and places it rotated 180 degrees out on the x, y grid of the destination substrate.

In contrast, in some embodiments, antenna aperture 300 has a radial point of symmetry and the die placement apparatus is controlled to translate the x and y repeating nature of wafer fabrication to the radial RF antenna element locations (e.g., the rings of RF antenna elements around center 303) of antenna aperture 300. In some embodiments, antenna aperture 300 has radial RF element pattern symmetry (e.g., the antenna aperture segments have a common origin), and the radial symmetry has die locations in antenna aperture 300 designated for antenna elements in rings. In some embodiments, the rings of antenna elements are of equal pitch. In addition to equally spaced rings, in some embodiments, the RF antenna elements are equally spaced around the rings. In addition to the radial and in radius pitch, in some embodiments, the RF antenna element patterns on antenna aperture 300 have an angle of +/−45 degrees with respect to the radius from center 303 of antenna aperture 300 to the center of each RF element. When placing dies to such antenna elements, in some embodiments, each die is placed in a known position with respect to the center of the die. Note that in some embodiments, the RF antenna element patterns on antenna aperture 300 have an angle slightly shifted from +/−45 degrees or slight shifts in antenna element pitch (along a ring) or radius (yet the antenna elements are still addressable by an (r, theta) system. In some embodiments, the shifts compensate for antenna element-to-antenna element coupling. In some embodiments, the shirts are enough to reduce or substantially eliminate antenna element-to-antenna element coupling, thereby improving performance.

In some embodiments, a method is used to place antenna aperture 300 (or segments thereof) on platen 301 where the die placement on antenna aperture 300 (or segment thereof) is with respect to the center 303 of antenna aperture 300, which is coincident to the center of revolution of platen 301. In some embodiments, there are alignment marks on platen 301 corresponding to alignment marks on antenna aperture 300 (or aperture segments) to place the segments accurately with respect to the origin (r=0, angle=0) of the revolving platen 301. In some embodiments, the origin of antenna aperture 300 (or aperture segment thereof) may not be physically within the aperture or aperture segment.

In some embodiments, die placement tool 320 (e.g., pick and place machine) is programmed so that, for placement of the die on a given ring, the placement is on the radius of that ring, and at the proper polar angle coordinate. Platen 301 presents the RF element on antenna aperture 300 (or segment) to die placement tool 320 so that the bond pads on the iris of the RF element coincide with the bond pads of the presented RF element.

In some embodiments, platen 301 is also mounted to linear, or translation, stage 310, which moves platen 301 so that the RF antenna elements on a ring (equal radius to the aperture center/center pivot point of the revolving platen) are presented to die placement tool 320 one ring at a time. In some embodiments, the movement of linear stage 310 need only be a little over the aperture radius. Thus, in some embodiments, platen 301 controls the angle (theta) and linear stage 310 controls the ring radius (r) to present each RF element location in the same way to die placement tool 320 each time.

In some embodiments, along each RF element ring on antenna aperture 300, there are different types of RF antenna elements that each require a different type of die. For the elements within a ring, the RF antenna elements have a set of angle values of the ring angle pitch. For a ring, the placement increments the revolution the appropriate number of angle pitches as needed by the elements.

To place the next ring, linear stage 310 moves the revolving plate to the appropriate ring and the die placement of that ring begins, thereby causing the revolving platen 301 to move to the correct angle for each RF antenna element on the ring.

In some embodiments, the dies on tape 330 may be oriented at an angle to the rotating placement arm 321 that picks up each die as shown in FIG. 3. In some embodiments, the die may be oriented with parallel or perpendicular to placement arm 321. In some embodiments, the orientation of the bond pads for the die on the iris of the RF antenna element (for bonding the die) determines the angle of the die on tape 330. Note that in some embodiments, the dies may be on a tape with some space between them, and the tape is, in turn, mounted on a frame (e.g., a circular frame, a non-circular frame, etc.). The frame is mounted on an x-y stage, and as part of the set-up, there is a way to rotate each die on it to a desired angle. In some embodiments, the frame is mounted to the x-y stage so that the lines of die match the x-y axis of the stage that presents the die to the pick-up nozzle of the die placement tool, the x-y stage would be in turn be lined up with the x-y axis of the stage that holds the antenna aperture. In some embodiments, techniques are used to make corrections to line up these parts of the machine with corrections completed by modifying the frames to make the accommodation.

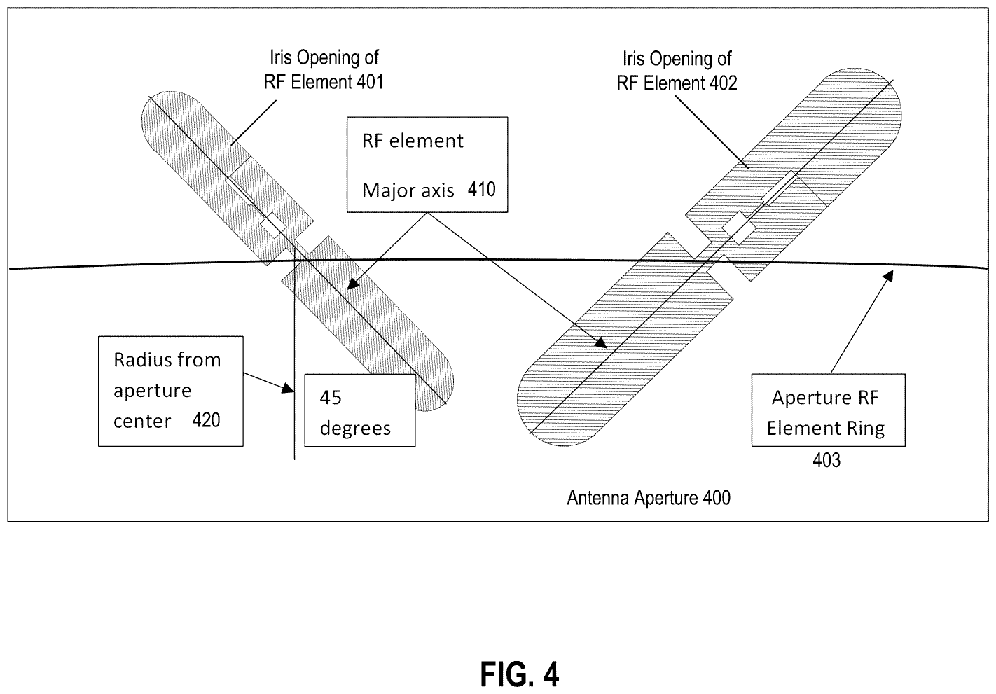

In some embodiments, along a ring, the major axes of the RF antenna elements are placed at angles of +45 or −45 with respect to a radius drawn from the center of the RF antenna element to the aperture center. FIG. 4 illustrates portions of a pair of RF antenna elements. Referring to FIG. 4, RF antenna element 401 and RF antenna element 402 are shown with their iris openings. A major axis 410 runs through the elongated portion of the iris openings of RF elements 401 and 402. In some embodiments, the center of RF elements 401 and 402 are on a RF element ring on the aperture 400. RF element 401 and 402 are at 90 degrees with respect to each other and 45 degrees with respect to the radius from aperture center 420 (e.g., center 303 of aperture 300).

In some embodiments, die placement requires that the bond pads of the die be placed to match the two orientations shown. In some other embodiments, the die bond pads on the aperture may be placed at repeating angle such as +45 degrees or −45 degrees with respect to the radius from the aperture center through the center of the iris element. In some embodiments, for RF antenna elements that are alternating at +45 or −45 with respect to a ring radius in the system, the die orientation is rotated before or during placement to enable rotating platen 301 to properly position the RF elements for die placement.

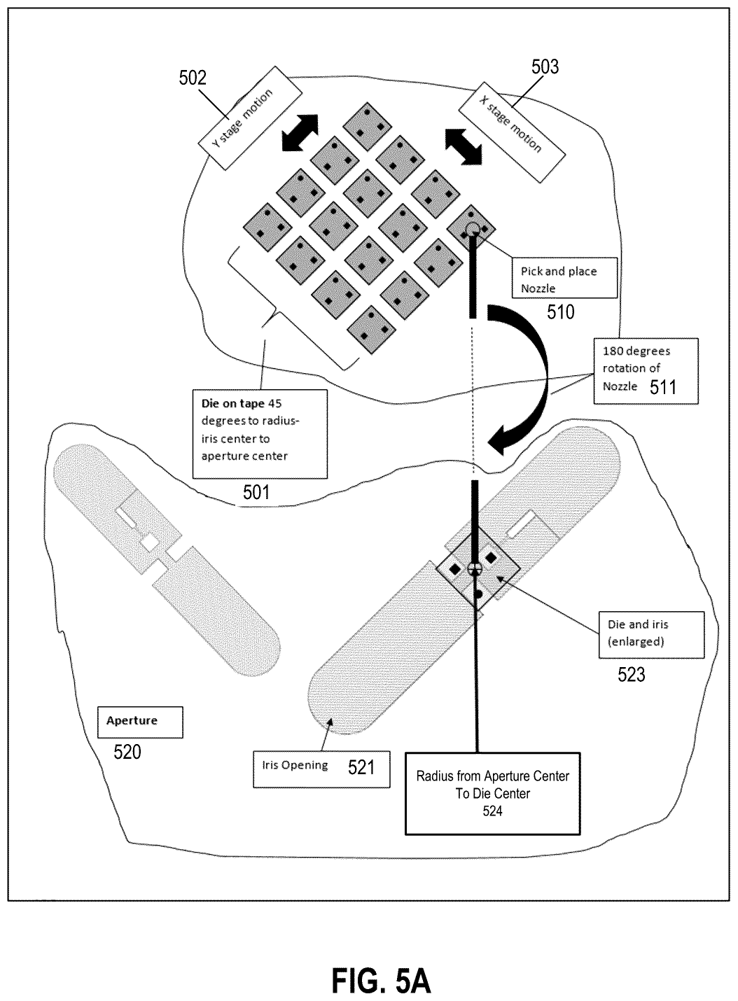

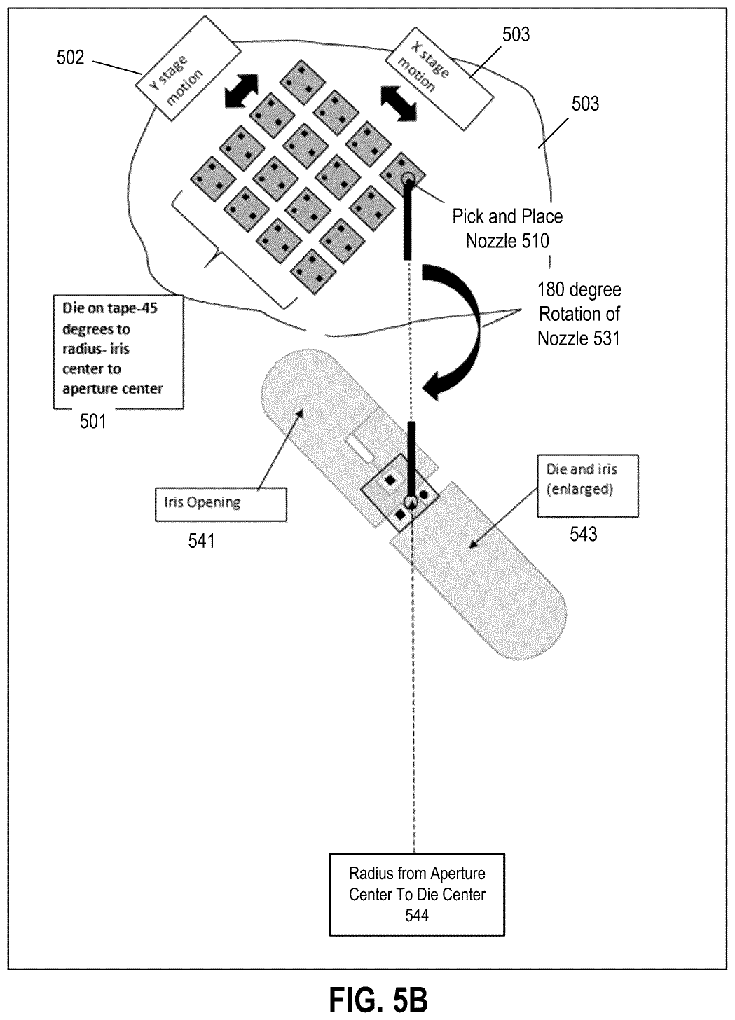

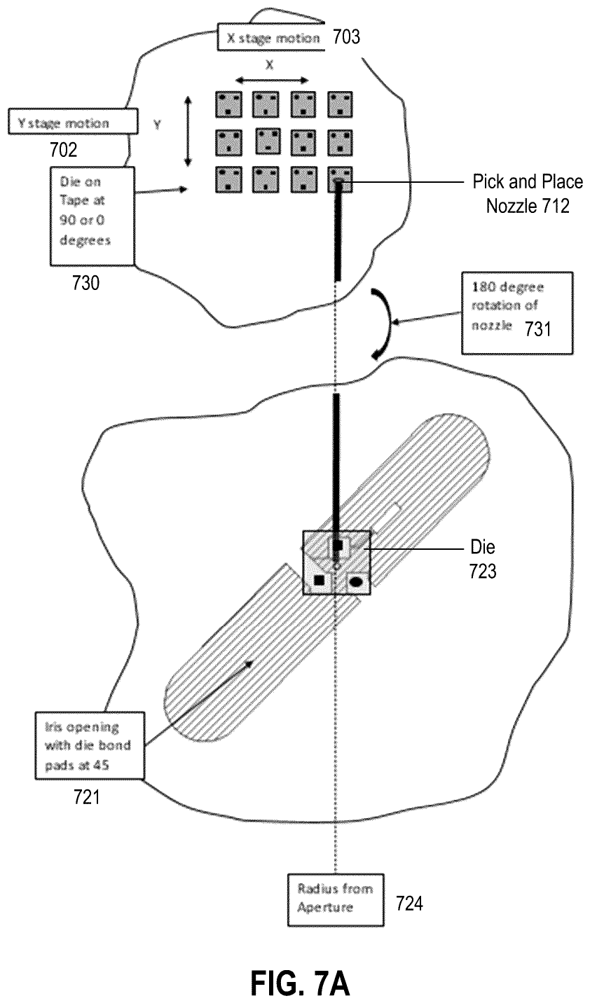

In some embodiments, when making die on a semiconductor with crystal orientation, there may not be an option to print the die in the orientation one desires for subsequent pick and placement. Furthermore, if the pick and place equipment being used only has the ability to place the at 0 degrees, 90 degrees, with respect to the antenna aperture segment edges, then the bond pad locations per RF element need to changed and the segment rotate as needed to place the die. Techniques disclosed herein resolve the issue in a couple of ways and are described in FIGS. 5A and 5B (as well as FIG. 7).

To address this situation in one way, in some embodiments, the die on the tape is oriented at 45 degrees with respect to the rotation nozzle of the die placement tool. FIG. 5A illustrates some embodiments in which the die orientation is set to enable a pick and place machine (or other die placement tool) to pick and place individual dies by rotating the dies 180 degrees using the nozzle of the rotating placement arm of a pick and place machine.

Referring to FIG. 5A, tape 501 includes a number of dies and the dies are positioned on tape 501 at 45 degrees with respect to the radius-iris center from the center of the antenna aperture onto which the dies are to be placed. Tape 501 is capable of moving in the x and y directions using Y range motion 502 and X range motion 503, respectively, via an X-Y stage on which tape 501 resides. The pick and place nozzle 510 picks up a die from tape 501 that is placed beneath nozzle 510 using X stage motion 502 and Y stage motion 503 and rotates the die 180 degrees (511) to place the die on iris 523. In some embodiments, the die is placed at on iris opening 524 on aperture 520 at a 45 degree angle with respect to the radius 524 from the aperture center to iris hole 522. Note that in some embodiments, the die has a thin film transistor (TFT) connection pad that points away from the aperture center in FIG. 5A (where the TFT is a transistor that is part of a matrix drive and is used to drive a tuning voltage onto an antenna element).

In some embodiments, the dies for RF antenna elements in this orientation are placed on the rings. In some embodiments, when placement of die required for this orientation are completed, the tape is rotated by 90 degrees, and the dies required by the RF antenna elements in the −45 degree orientation are placed on the rings. FIG. 5B illustrates the placement of dies required by the RF antenna elements in the −45 degree orientation.

Referring to FIG. 5B, another set of the dies on tape 501 are to be placed onto other RF antenna elements that each have an iris. In this case, the dies on tape are rotated at 90 degree with respect to those in FIG. 5A and each die is to be placed on an iris opening such as iris opening 541 that has an iris hole 542. Die 543 is placed on iris opening 541 after being rotated 180 degrees 531 using pick and place nozzle 510. Note that in some embodiments, the die has a thin film transistor (TFT) tuning voltage bond pad that points away from the aperture center in FIG. 5B (where the TFT is a transistor that is part of a matrix drive and is used to drive a tuning voltage onto an antenna element).

Note that the dies appear as being the same type in FIGS. 5A and 5B. However, in some embodiments, the die on these tapes may be of multiple types corresponding to the types of RF antenna elements that are part of the aperture (e.g., different types of RF antenna elements on the rings of the aperture, etc.). For example, the dies can contain different components (e.g., components with different electrical characteristics) where the RF antenna elements are different sizes (e.g., receive and transmit RF antenna elements being different sizes, multiple transmit RF antenna elements on the aperture of different sizes, multiple receive RF antenna elements on the aperture of different sizes, etc.).

Note that in the case of FIGS. 5A and 5B, the dies with the varactor element line up with the minor axis of the antenna elements. However, examining FIGS. 5A and 5B, the tape is rotated to populate the FIG. 5B case, which means the die placement apparatus needs to intervene to cause this rotation.

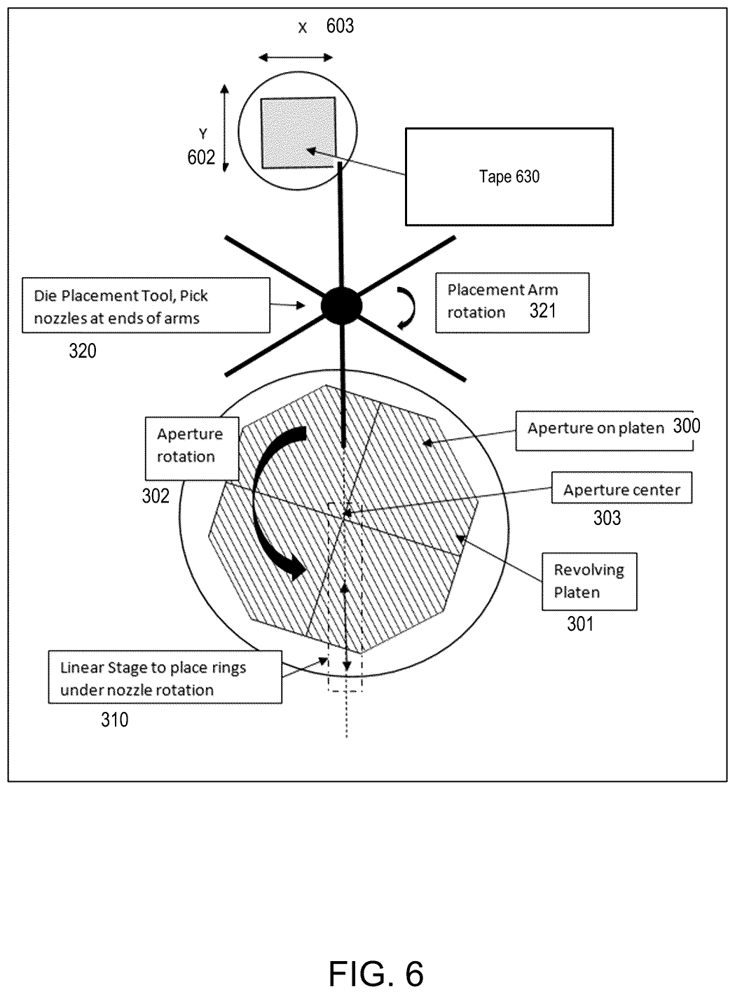

There are a number of placement options if the dies on the tape are held at 0 degrees or 90 degrees with respect to the revolving placement arm of a die placement tool. FIG. 6 illustrates some embodiments of the die placement apparatus where the dies on the tape are held at 0 or 90 degrees with respect to the revolving placement arms of the die placement tool (e.g., die placement tool 320 of FIG. 3, a pick and place machine, etc.). Referring to FIG. 6, tape 630 is on the X-Y stage that permits motion of tape 630 in the Y direction 602 and X direction 603. The block of dies are at 45 degree angles with respect to the dies from FIGS. 5A and 5B. In this case, the die bond pad placement orientations within the RF antenna element are not the same. Examples are shown in FIGS. 7A and 7B, which illustrate using a mirror of the RF element described above with pad placement orientations within the RF antenna elements not being the same. In the case of FIGS. 7A and 7B, the tape presents the die at 0 degrees, 90 degrees to a rotating arm of the die placement tool and the bond pads of the −45 and +45 RF elements are different, namely rotated 45 or −45 with respect to the RF elements minor axis to compensate for the dies being at 0 degrees, 90 degrees.

Referring to FIG. 7A, the dies of the tape 730 are in rows and columns and the tape can be moved by an X-Y stage (on which tape 730 resides) to have Y stage motion 702 or X stage motion in the X direction 703. The pick and place nozzle 712 on the end of a rotating arm of the pick and place machine picks up one of the dies on tape 730, rotates it 180 degrees 731, and places die 723 on iris opening 721 with bond pads that are at a 45 degree angle with respect to die 723. In this case, die 723 is aligned with, but rotated 180 degrees from its orientation on the tape, with respect to the radius 724 from the antennas.

For die placement purposes, in FIGS. 7A and 7B, the angle of the axis of the RF elements is compensated by the rotation of the bond pads, rather than the rotation of the die on the tape as was done in FIGS. 3, 5A and 5B. This results in the same bond pad pattern for both +45 and −45 RF elements. If two element are mirrored across the radius from the aperture, the bond pattern is the same, which means the placement can take place without rotating the tape to orient the die by +45 degrees or −45 degrees as was done in FIGS. 5A and 5B. For example, referring to FIG. 7B, the dies of the tape 730 are in rows and columns and the tape may be moved by an X-Y stage (on which tape 730 resides) to have Y stage motion 702 or X stage motion in the X direction 703 to place a die under pick and place nozzle 712 of the pick and place machine. Pick and place nozzle 712 on the end of a rotating arm of the pick and place machine picks up one of the dies on tape 730, rotates it 180 degrees 731, and places die 743 on iris opening 741 with bond pads that are at a 45 degree angle with respect to die 743. In this case, die 743 is aligned with, but rotated 180 degrees from its orientation on the tape, with respect to the radius 744 from the antennas.

In some embodiments, techniques disclosed herein are used when routing a circuit of the aperture or aperture segment to RF elements of the antenna aperture is from the center of the aperture outward. For routing the circuit of an aperture or aperture segment, there is an advantage to be able to make the connection to the TFT (e.g., the TFT described above) from either end of the RF antenna element. In some embodiments, for the rotation of the die, to allow the electrical connection from the TFT to enter the RF antenna element from either end, the die may be processed and flipped on the wafer, so that the pick and place machine (or other die placement tool) can flip the die connection in the aperture during placement, while preserving the placement of the die (e.g., varactor for varactor-based antenna elements, etc.) and MIM along the preferred crystal axis.

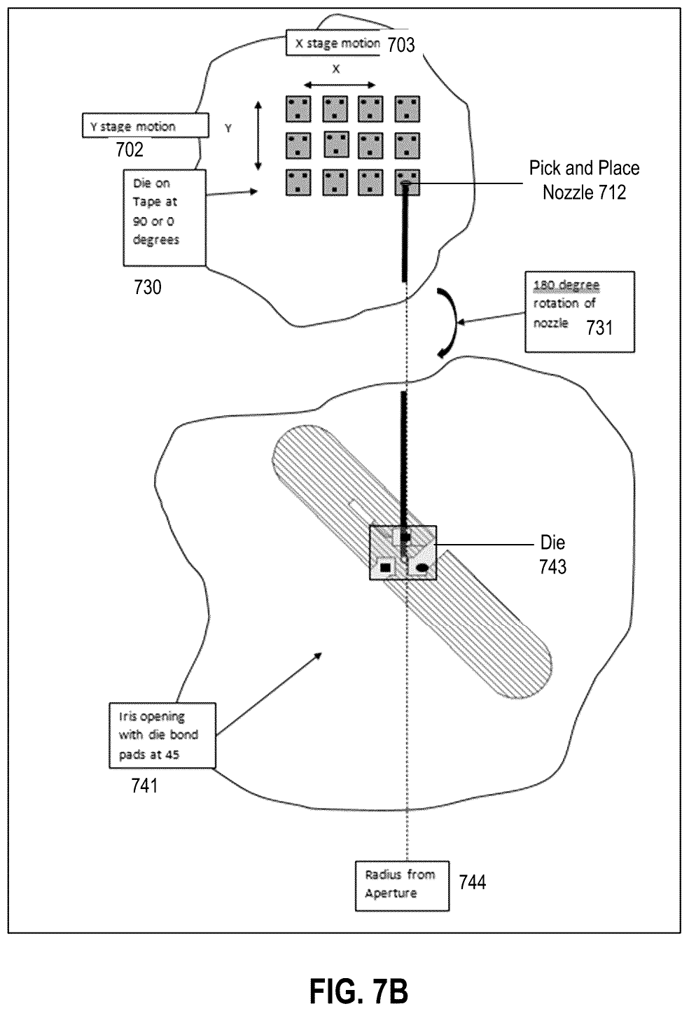

FIG. 8 illustrates the die orientation rotated 180 degrees in the z-direction on as shown by the dies in adjacent columns in FIG. 8 being different. Referring to FIG. 8, the die orientation 802 of dies 800 are flipped for each of the columns going across the Y direction that is aligned with the preferred crystal axis 801.

For routing purposes, there is an advantage to having the routing to the data pad enter from either side of the RF element (e.g., from the side of the previous ring, or from the side of the following ring.). Instead of accomplishing this by manually rotating the antenna aperture segment, one can flip the die orientation as shown in FIG. 8, thereby allowing the routing of the data line to come in from either side of the ring. In such a case, by knowing the layout allows putting the die from the correct orientation.

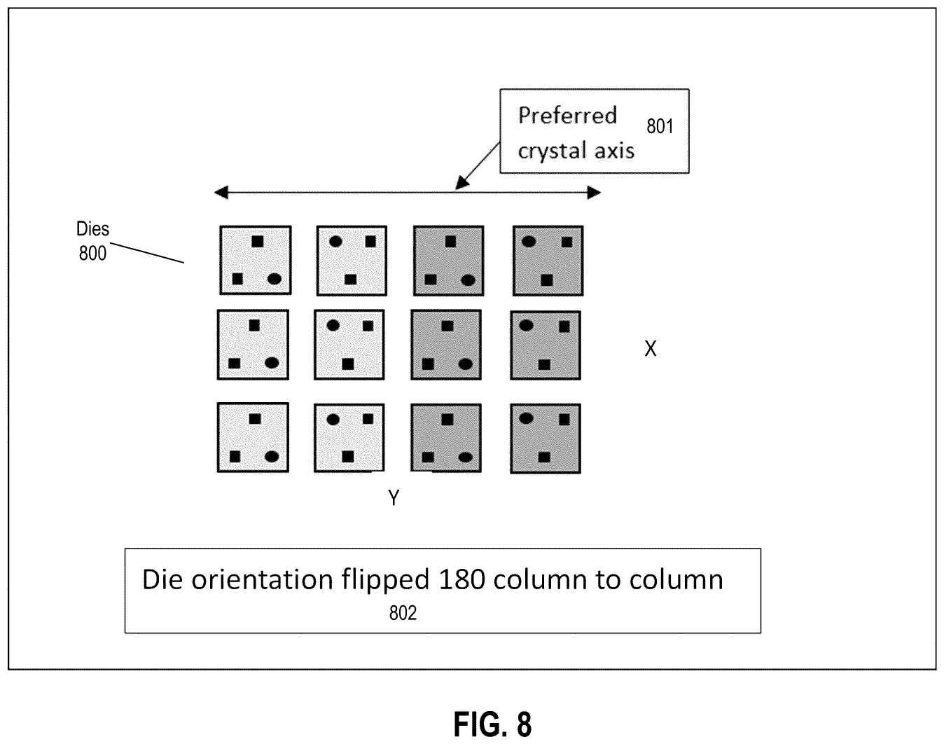

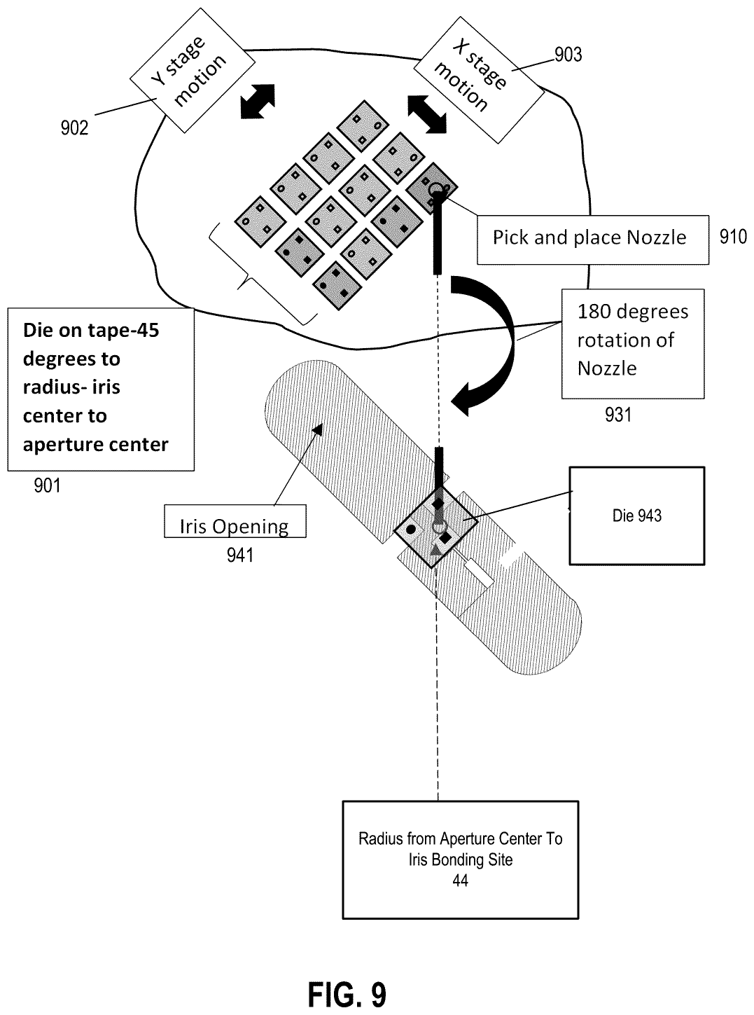

Also, FIG. 8 shows two types of varactors (varactors of two shades of gray). These different varactors types are for different kinds of RF elements may be made on the same wafer using the same processing. Therefore, in some embodiments, if placing the die on the rings of an aperture of aperture segment, and proceeding along a row in FIG. 8, two RF element orientations (+45,−45) of one type RF element can be placed (per FIGS. 10A and 10B discuss below), with two routing configurations (such as FIGS. 5B and 9) and the tape oriented at 90 degrees (per FIGS. 7A and 7B) to allow rotations (FIGS. 10A and 10B). Also, multiple types of RF elements (e.g., varactors of different grays of FIG. 8). This would allow one tape type, which can be made from one wafer type, where the dies could all be arranged in the correct order to fit the pattern of the RF elements on the antenna aperture (or aperture segment). In this way, the set ups and machine movements for the die placement tool are reduced, and potentially minimized. In this approached, the aperture/aperture segments is designed with RF element layouts that match this scheme.

In some embodiments, the contact pads of each die (e.g., TFT contact pads) point toward the aperture center. FIG. 9 illustrates a placement method for placing a die where a TFT connection is desired to be oriented toward the aperture center. This illustration shows a placement method of the die where TFT connection is desired to be oriented toward the aperture center. In some embodiments, this is achieved by having die of the correct crystal orientation laid out at both 0 degrees and 180 degree on the tape. In some embodiments, this is achieved by laying out die of both orientations on the wafer in the proper order, or by sorting and placement on the tape.

Referring to FIG. 9, tape 901 includes multiple dies and is movable via an X-Y stage (on which tape 901 resides) in terms of X stage motion 903 and Y stage motion 902. The rotating arm of a pick and place machine has a pick and place nozzle 910 that picks up one of the dies that is positioned under nozzle 910 using the X-Y stage, rotates the die 180 degrees 931, and places it on iris opening 941 such that the die 943 shown on the iris opening 941 appear as one. In some embodiments, die 943 is placed over iris opening 941 and is at a 45 degree angle with respect to the radius 944 of the aperture center.

### Wafer and Tape Preparation

In some embodiments, to maximize speed, the movement of each stage (tape, revolving platen) are kept as small as possible. In some embodiments, since the die type and orientation on the aperture segment requirement in each orientation are known, tapes with each die type and desired orientation are placed in an optimized order on the tape. As a further step the order of the die type and orientation are optimized on the wafer to enable preparation of the order on the tape or reel. This optimization may be done in several ways.

In some embodiments, wafers are prepared with the die types of all the same orientation (rotated to the proper orientation during placement). These are sorted to make the optimized order on the tape. In some embodiments, wafers and tapes are prepared where all of the die types and required orientations are present and the die placement machine sorts them. In some embodiments, wafers and die tapes are prepared with all of the die types and orientation, but they are presorted by orientation to prepare tapes. In some embodiments, tapes are prepared to enable tapes to be rotated for placement of each orientation. In some embodiments, wafers are prepared to enable dies to be placed on tapes in the order of placement by (die type, orientation) for aperture/aperture segment rings.

In some embodiments, the numbers of die types/orientations are nearly equal for an aperture/aperture segment, and wafers and corresponding tapes are prepared where each die type/orientation are present in a repeating block order such that, for each required die, there is a small stage movement to present the proper die to the pick and place nozzle.

In some embodiments, the die placements are performed such that the iris elements of the bond pads are oriented at 45 degrees in a mirrored configuration between the two different rotations. If the die placement can be done by iris elements with bond pads oriented at +45 degrees in a mirrored configuration, then the need to flip die by +45 degrees or rotate the tape for placement may be ignored. FIGS. 10A and 10B illustrate such an arrangement. Referring to FIGS. 10A and 10B, the pick and place nozzle 1012 at the end of a rotating arm of the die placement tool is positioned to pick up a die on a tape, rotated 180 degrees 1031 and place it on iris opening 1021 or 1022 such as the dies 1023 and 1025, respectively, are oriented the same way even though iris openings 1021 and 1022, respectively, are oriented 90 degrees with respect to each other.

In some embodiments, at this point, the pattern of antenna elements on a ring repeats such as Tx (transmit), Rx (receive), Tx, Rx, etc. . . . for each ring of RF antenna elements throughout the aperture for the areas where the TFT connections are pointed away from the aperture center. In areas where the TFT connection points toward the aperture center, the orientation of the Tx, Rx can be rotated on the wafer by 180 degrees. If only an aperture segment were being placed on a platen (as opposed to the entire aperture), the rings can begin with a Tx element and at the end of a ring the last element would be a Rx element (going counter clockwise as in the segment drawing). To aid in placement, the ring spacing is incremented, and a reverse rotation is performed, and potentially the placement would go Rx, Tx, Rx, Tx, etc. to the end of the ring of antenna elements. In contrast, if placing an aperture, or all aperture segments forming a complete aperture (e.g., four quarter segments) on a platen, then a ring (going counter clockwise) of antenna elements could begin with an Tx element and end with an Rx element, increment by a ring pitch, and continue placing without reversing the pattern.

Note that alternative mechanisms of achieving a flipping the die orientation by +45 degree can be performed using an off axis die placement machine. In some embodiments, for some die placement machine embodiments, the +45 and −45 degree angles are achieved by rotating the RF element to the proper 45 degree angle on the revolving platen with respect to die on tape that are at 90 degrees with respect to the nozzle (die on tape not rotated), and then by placing on an RF element presented at a 45 degree angle (center of the rotating arm on the die placement machine and the center of the revolving platen are not always colinear).

In some embodiments, the platen moves linearly at a 45 with respect to the rotating arm center so the revolving platen presents to the bonds pads of the RF element to a 90 degree oriented die. In some embodiments, the bond pad patterns for every RF element are very nearly the same. This may reduce the variation in performance between RF elements. In some embodiments, there could be multiple pick and place machines working from each side are around a platen.

In some embodiments, multiple dies are placed at a time. In some embodiments, two dies are placed at a time. Such a die placement arrangement can take advantage of repeating two element +45 degree to −45 degree flip to place two die at a time.

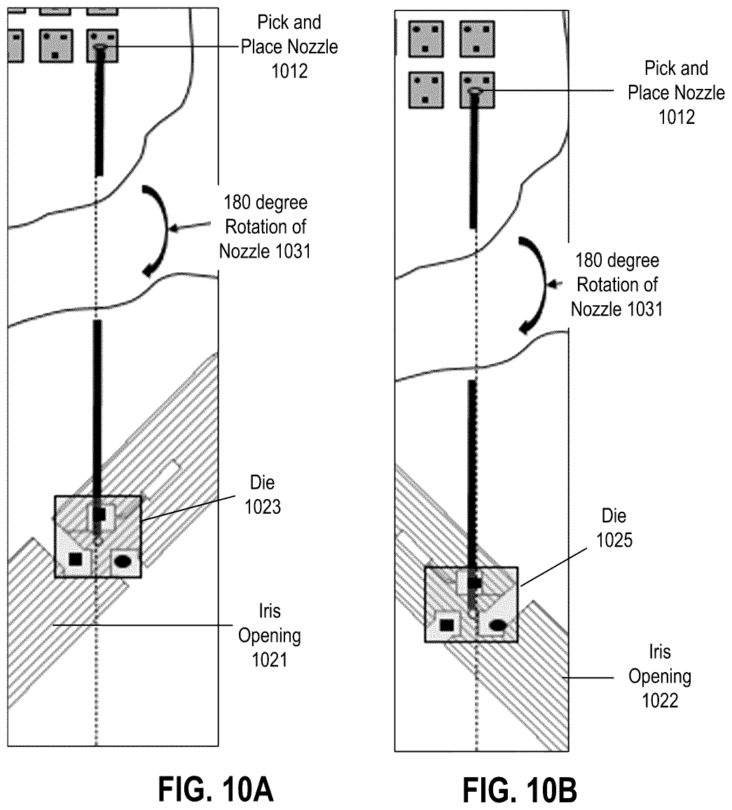

In some embodiments, the antenna has RF elements that are part of the same pattern across the antenna aperture. However, when an aperture is comprises of multiple aperture segments (e.g., four antenna aperture segments joined to form a single antenna aperture, etc.), the pattern can be disrupted at the seams between the antenna segments. Except for the seam elements where aperture segments meet and are joined (actually the same pattern but with elements missing), there is another pattern within the rings. In some embodiments, this is a {Rx (+45), Tx (+45)}, {Rx (−45), Tx(−45} die orientation pattern. However, other patterns can be used. To take advantage of this pattern, in some embodiments, two nozzles can be placed at 90 degrees to the rotating arm of the die placement machine. In some embodiments, the pattern continues for each ring, adding a pair of RF antenna elements to each quadrant for each ring pitch increment. FIG. 11 illustrates two RF antenna elements being added to each quadrant for each ring pitch increment.

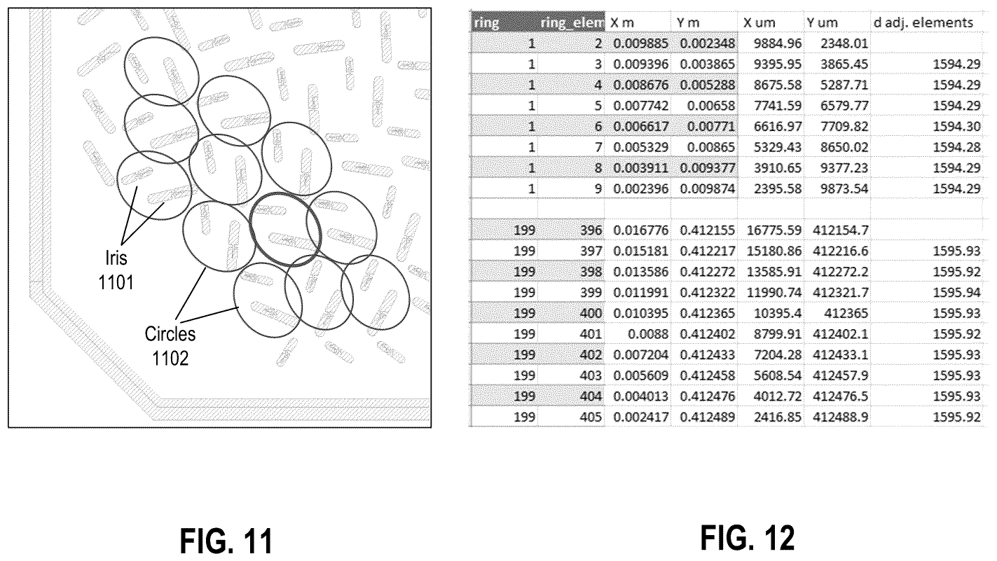

In some embodiments, the distance between these pairs of RF antenna elements is not exactly the same for each ring, and the distance grows slightly as the rings get bigger. However, the distance change between the RF antenna elements is small, which is shown in the first 8 elements and the last 10 element in the segment placement table in FIG. 12 (the coordinates of each RF antenna element are used to calculate the distance between the RF antenna elements in the table in FIG. 12).

In some embodiments, the average difference in the distance in RF elements from the first ring to the last ring is about 1.64 microns. Note that in a solder reflow type of connection, the surface tension of the solder also helps align the die during the reflow process after a die has been placed onto the aperture.

In some embodiments, each rotating arm of die placement machine has two nozzles instead of one to pick up dies. In some embodiments, the nozzles are located at right angles to the major axis of each arm and are spaced at the average distance between the pairs of similarly oriented RF antenna elements. In some embodiments, these two nozzles use a tape with dies oriented perpendicularly to the major axis of the pick-up arms of the die placement machine, the die types of the dies on a tape are in the correct order, and the distance from die center to die center is of these die is close to the average die pitch (roughly 1595.1 um). More specifically, at a die pitch on the varactor wafer of 290 um, with no space between the die, the nozzles center to center=(total number of die*−1). For 5 dies on pitch a 290 um pitch, the nozzles from center to center would be 1160 um. To place dies on two RF antenna elements at roughly 1595 um spacing, an extra 435 um to be distributed over four gaps between the dies would be used, resulting in about 109 um gaps.

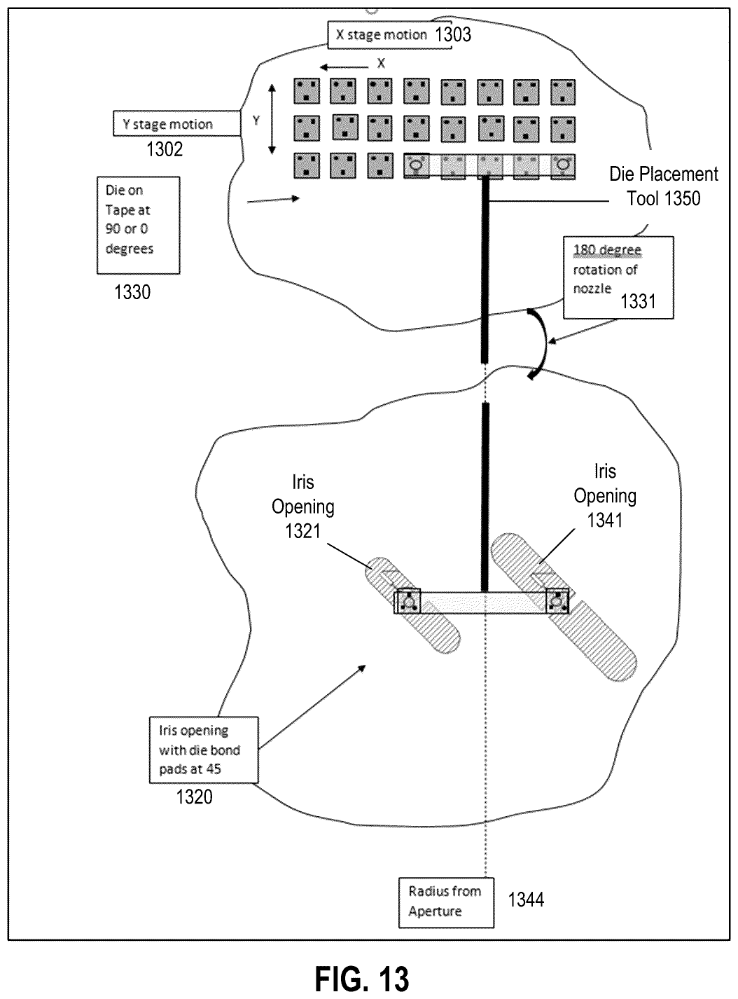

FIG. 13 illustrates placing two die at a time in some portions of an aperture or aperture segment. Referring to FIG. 13, a tape 1330 is on an X-Y stage that is able to move tape 1330 in the Y stage motion 1302 or X stage motion 1303 to position multiple dies under two nozzles at the end of a rotating arm of a die placement tool 1350. The rotating arm of a die placement tool 1350 is rotated 180 degrees where the dies are placed simultaneously over two iris openings of two antenna elements on the antenna aperture as the same time.

In some embodiments, the revolving platen for the aperture/aperture segments in this arrangement rotates to a midpoint between two similarly oriented antenna elements.

There are a number of example embodiments described herein.

Example 1 is a method for manufacturing an antenna aperture, where the method comprise: placing at least one portion of an antenna aperture on a platen that is radially revolvable, the at least one portion of the antenna aperture having a plurality of antenna elements; placing a plurality of dies on the at least one portion of the antenna aperture using a die placement machine, including radially revolving the platen with the machine to position each antenna element of the plurality of antenna elements of the at least one portion of the antenna aperture with respect to the machine for placement of each die of the plurality of dies, and placing said each die of the plurality of dies on the at least one portion of the antenna aperture segment.

Example 2 is the method of example 1 that may optionally include that bond pad pattern for each of the plurality of antenna elements on the at least one portion of the antenna aperture for use in bonding to one of the plurality of dies is substantially identical across the at least one portion.

Example 3 is the method of example 1 that may optionally include that the plurality of dies are picked up by the machine from a location, and when at the location, the plurality of dies includes groups of dies oriented in different orientations and the plurality of dies are located in an order at the location for pickup by the machine with some dies of different orientations adjacent to each other in the order.

Example 4 is the method of example 1 that may optionally include that the location comprises a tape or magazine.

Example 5 is the method of example 3 that may optionally include that the plurality of dies includes groups of dies oriented in different orientations and the plurality of dies are in an order for pickup by the machine with some dies of different orientations adjacent to each other in the order have orientations that are rotated 180 degrees with respect to each other.

Example 6 is the method of example 1 that may optionally include that the plurality of dies are picked up by the machine from a location from one of a plurality of tapes, each tape of the plurality of tapes being located at the location at a different time, wherein dies on each the plurality of tapes have an identical orientation but orientations of the dies are different between the plurality of tapes.

Example 7 is the method of example 1 that may optionally include that each die comprises a tuning element for one of the plurality of antenna elements.

Example 8 is the method of example 7 that may optionally include that the tuning element comprises a varactor.

Example 9 is the method of example 7 that may optionally include that the plurality of antenna elements have a plurality of types and each different type requires a different varactor.

Example 10 is the method of example 1 that may optionally include that the plurality of antenna elements are designed with the bond pad pattern rotated to compensate for the RF element rotation.

Example 11 is the method of example 1 that may optionally include: placing the antenna aperture on the platen, the antenna aperture having a polar symmetry corresponding to a center of rotation of the antenna aperture that corresponds with rotation of the platen, the antenna aperture having rings of RF antenna elements arranged in defined sequences around the center; and translating, by the machine, each die from a cartesian orientation to a polar orientation on the at least one antenna segment.

Example 12 is the method of example 11 that may optionally include that the antenna aperture comprises a plurality of RF antenna elements and a subset of RF antenna elements have a major axis at different angles with respect to a radius corresponding to the center of the aperture.

Example 13 is the method of example 12 that may optionally include that bond pads of each RF antenna element are oriented perpendicular to the major axis of said each RF antenna element and require a die oriented at a compensating angle.

Example 14 is the method of example 11 that may optionally include that the RF antenna elements are oriented at +45 degree or −45 degrees with respect to a radius corresponding to the center of the aperture.

Example 15 is the method of example 1 that may optionally include that the platen includes one or more alignment marks for placing the at least one at least one portion of the antenna aperture.

Example 16 is the method of example 1 that may optionally include that the platen is coupled to a translation stage to move the platen to cause RF radiating elements on a plurality of rings on the antenna aperture to be presented to the machine one ring at a time.

Example 17 is the method of example 16 that may optionally include that the platen controls an angle theta and the translation stage controls the ring radius to present each antenna element location in a same way to the machine each time.

Example 18 is the method of example 1 that may optionally include that bond pads on the at least one portion of the antenna aperture are placed to match one of two antenna element orientations or are placed at repeating angles with respect to a radius from the aperture center through the center of an iris of the antenna element. Example 19 is the method of example 1 that may optionally include that dies on tape are held to 0 and 90 degrees with respect to revolving arms of the machine when in a pickup position.

Example 20 is the method of example 1 that may optionally include that the bond pads for the plurality of dies are oriented with respect to a radius from the aperture center.

Example 21 is the method of example 1 that may optionally include that bond pads for the plurality of dies in the antenna aperture are rotated while preserving placement of each die along a crystal axis.

Example 22 is the method of example 1 that may optionally include that die type and orientation on the aperture segment are known, and further comprising setting up each die type and desired orientation in proper order on a tape at the location.

Example 23 is the method of example 1 that may optionally include that die type and orientation on the aperture segment are known, and further comprising setting up each die type and desired orientation in proper order on a wafer, and creating a tape from the wafer, including transferring the plurality of dies to the tape with each die type and desired orientation in proper order on the tape.

Example 24 is the method of example 1 that may optionally include rotating a die orientation using an off axis die placement machine.

Example 25 is the method of example 1 that may optionally include that the plurality of dies are different dies from a single wafer.

Example 26 is the method of example 1 that may optionally include that the RF antenna elements are oriented in a manner slightly shifted from +45 degree or −45 degrees with respect to a radius corresponding to the center of the aperture.

Example 27 is an apparatus for manufacturing an antenna aperture, where the apparatus comprises: a radially revolvable platen for holding placing at least one portion of an antenna aperture that has a plurality of antenna elements; a die placement tool to place a plurality of dies on the at least one portion of the antenna aperture, by obtaining each die of the plurality of dies from a location with a nozzle of a rotating arm of the die placement tool, and placing said each die on one antenna element of the plurality of antenna elements after radially revolving the platen to revolve the at least one portion of the antenna aperture to position said each antenna element beneath the die in the nozzle of the die placement tool holding said each die.

Example 28 is the apparatus of example 27 that may optionally include that wherein a bond pad pattern for each of the plurality of antenna elements on the at least one portion of the antenna aperture for use in bonding to one of the plurality of dies is substantially identical across the at least one portion.

Example 29 is the apparatus of example 27 that may optionally include that the plurality of dies are picked up by die placement tool from the location and placed without rotating each of the plurality of dies, and when at the location, the plurality of dies includes groups of dies oriented in different orientations and the plurality of dies are located in an order at the location for pickup by the die placement tool with some dies of different orientations adjacent to each other in the order.

Methods and tasks described herein may be performed and fully automated by a computer system. The computer system may, in some cases, include multiple distinct computers or computing devices (e.g., physical servers, workstations, storage arrays, cloud computing resources, etc.) that communicate and interoperate over a network to perform the described functions. Each such computing device typically includes a processor (or multiple processors) that executes program instructions or modules stored in a memory or other non-transitory computer-readable storage medium or device (e.g., solid state storage devices, disk drives, etc.). The various functions disclosed herein may be embodied in such program instructions, or may be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid-state memory chips or magnetic disks, into a different state. In some embodiments, the computer system may be a cloud-based computing system whose processing resources are shared by multiple distinct business entities or other users.

Depending on the embodiment, certain acts, events, or functions of any of the processes or algorithms described herein can be performed in a different sequence, can be added, merged, or left out altogether (e.g., not all described operations or events are necessary for the practice of the algorithm). Moreover, in certain embodiments, operations or events can be performed concurrently, e.g., through multi-threaded processing, interrupt processing, or multiple processors or processor cores or on other parallel architectures, rather than sequentially.

The various illustrative logical blocks, modules, routines, and algorithm steps described in connection with the embodiments disclosed herein can be implemented as electronic hardware (e.g., ASICs or FPGA devices), computer software that runs on computer hardware, or combinations of both. Moreover, the various illustrative logical blocks and modules described in connection with the embodiments disclosed herein can be implemented or performed by a machine, such as a processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the rendering techniques described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, routine, or algorithm described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements or steps. Thus, such conditional language is not generally intended to imply that features, elements or steps are in any way required for one or more embodiments or that one or more embodiments necessarily include logic for deciding, with or without other input or prompting, whether these features, elements or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, or Z). Thus, such disjunctive language is not generally intended to, and should not, imply that certain embodiments require at least one of X, at least one of Y, and at least one of Z to each be present.

While the above detailed description has shown, described, and pointed out novel features as applied to various embodiments, it can be understood that various omissions, substitutions, and changes in the form and details of the devices or algorithms illustrated can be made without departing from the spirit of the disclosure. As can be recognized, certain embodiments described herein can be embodied within a form that does not provide all of the features and benefits set forth herein, as some features can be used or practiced separately from others. The scope of certain embodiments disclosed herein is indicated by the appended claims rather than by the foregoing description. All changes which come within the meaning and range of equivalency of the claims are to be embraced within their scope.

We claim:

1. A method for manufacturing an antenna aperture, the method comprising:
placing at least one portion of an antenna aperture on a platen that is radially revolvable, the at least one portion of the antenna aperture having a plurality of antenna elements;
placing a plurality of dies on the at least one portion of the antenna aperture using a die placement machine, including
radially revolving the platen with the machine to position each antenna element of the plurality of antenna elements of the at least one portion of the antenna aperture with respect to the machine for placement of each die of the plurality of dies, and
placing said each die of the plurality of dies on the at least one portion of the antenna aperture segment.

2. The method of claim 1 wherein bond pad pattern for each of the plurality of antenna elements on the at least one portion of the antenna aperture for use in bonding to one of the plurality of dies is substantially identical across the at least one portion.

3. The method of claim 1 wherein the plurality of dies are picked up by the machine from a location, and when at the location, the plurality of dies includes groups of dies oriented in different orientations and the plurality of dies are located in an order at the location for pickup by the machine with some dies of different orientations adjacent to each other in the order.

4. The method of claim 3 wherein the location comprises a tape or magazine.

5. The method of claim 1 wherein the plurality of dies includes groups of dies oriented in different orientations and the plurality of dies are in an order for pickup by the machine with some dies of different orientations adjacent to each other in the order have orientations that are rotated 180 degrees with respect to each other.

6. The method of claim 1 wherein the plurality of dies are picked up by the machine from a location from one of a plurality of tapes, each tape of the plurality of tapes being located at the location at a different time, wherein dies on each the plurality of tapes have an identical orientation but orientations of the dies are different between the plurality of tapes.

7. The method of claim 1 wherein each die comprises a tuning element for one of the plurality of antenna elements.

8. The method of claim 7 wherein the tuning element comprises a varactor.

9. The method of claim 8 wherein the plurality of antenna elements has a plurality of types and each different type requires a different varactor.

10. The method of claim 1 wherein antenna elements of the plurality of antenna elements are designed with the bond pad pattern rotated to compensate for the RF element rotation.

11. The method of claim 1 further comprising:
placing the antenna aperture on the platen, the antenna aperture having a polar symmetry corresponding to a center of rotation of the antenna aperture that corresponds with rotation of the platen, the antenna aperture having rings of RF antenna elements arranged in defined sequences around the center; and
translating, by the machine, each die from a cartesian orientation to a polar orientation on the at least one antenna segment.

12. The method of claim 11 wherein the antenna aperture comprises a plurality of RF antenna elements and a subset of RF antenna elements have a major axis at different angles with respect to a radius corresponding to the center of the aperture.

13. The method of claim 12 wherein bond pads of each RF antenna element are oriented perpendicular to the major axis of said each RF antenna element and require a die oriented at a compensating angle.

14. The method of claim 11 wherein the RF antenna elements are oriented at +45 degree or −45 degrees with respect to a radius corresponding to the center of the aperture.

15. The method of claim 1 wherein the platen includes one or more alignment marks for placing the at least one at least one portion of the antenna aperture.

16. The method of claim 1 wherein the platen is coupled to a translation stage to move the platen to cause RF radiating elements on a plurality of rings on the antenna aperture to be presented to the die placement machine one ring at a time.

17. The method of claim 16 wherein the platen controls an angle theta and the translation stage controls the ring radius to present each antenna element location in a same way to the die placement machine each time.

18. The method of claim 1 wherein bond pads on the at least one portion of the antenna aperture are placed to match one of two antenna element orientations or are placed at repeating angles with respect to a radius from the aperture center through the center of an iris of the antenna element.

19. The method of claim 1 wherein dies on tape are held to 0 and 90 degrees with respect to revolving arms of the die placement machine when in a pickup position.

20. The method of claim 1 wherein the bond pads for the plurality of dies are oriented with respect to a radius from the aperture center.

21. The method of claim 1 wherein bond pads for the plurality of dies in the antenna aperture are rotated while preserving placement of each die along a crystal axis.

22. The method of claim 1 wherein die type and orientation on the aperture segment are known, and further comprising setting up each die type and desired orientation in proper order on a tape at the location.

23. The method of claim 1 wherein die type and orientation on the aperture segment are known, and further comprising:
setting up each die type and desired orientation in proper order on a wafer, and
creating a tape from the wafer, including transferring the plurality of dies to the tape with each die type and desired orientation in proper order on the tape.

24. The method of claim 1 further comprising rotating a die orientation using an off axis die placement machine.

25. The method of claim 1 wherein the plurality of dies are different dies from a single wafer.

26. The method of claim 11 wherein the RF antenna elements are oriented in a manner slightly shifted from +45 degree or −45 degrees with respect to a radius corresponding to the center of the aperture.

27. An apparatus for manufacturing an antenna aperture, the apparatus comprising:
a radially revolvable platen for holding placing at least one portion of an antenna aperture that has a plurality of antenna elements;
a die placement tool to place a plurality of dies on the at least one portion of the antenna aperture, by
obtaining each die of the plurality of dies from a location with a nozzle of a rotating arm of the die placement tool, and
placing said each die on one antenna element of the plurality of antenna elements after radially revolving the platen to revolve the at least one portion of the antenna aperture to position said each antenna element beneath the die in the nozzle of the die placement tool holding said each die.

28. The apparatus of claim 27 wherein a bond pad pattern for each of the plurality of antenna elements on the at least one portion of the antenna aperture for use in bonding to one of the plurality of dies is substantially identical across the at least one portion.

29. The apparatus of claim 27 wherein the plurality of dies are picked up by die placement tool from the location and placed without rotating each of the plurality of dies, and when at the location, the plurality of dies includes groups of dies oriented in different orientations and the plurality of dies are located in an order at the location for pickup by the die placement tool with some dies of different orientations adjacent to each other in the order.
